(19) United States
(12) Patent Application Publication
(10) Pub. No.: US 2008/0189213 A1
(43) Pub. Date: Aug. 7, 2008

(54) System and method for digital rights management with license proxy for mobile wireless platforms

(76) Inventors: Curtis Blake, Fair Oaks, CA (US); Robert Kellogg, Purcellville, VA (US); Robert Bernardi, Bethesda, MD (US)

Correspondence Address: Benman, Brown & Williams, Ste. 2740, 2049 Century Park East, Los Angeles, CA, 90067, US

(21) Appl. No.: 11/702,688

(22) Filed: Feb. 5, 2007

(51) Int. Cl. G06Q 99/00; H03M 1/00

(52) U.S. Cl. 705/59; 705/57; 705/58

(57) ABSTRACT

A digital rights management system for wireless platforms. The system includes client software running on the wireless platform for publishing and/or viewing protected content. Enterprise server code is executed on a first server platform for sending and receiving protected content. An extension on the enterprise server code is included for detecting the presence of protected content, storing any such protected content in memory and substituting new content for the protected content for viewing on the wireless platform. A digital rights management server provides licenses for viewing the protected content on the wireless platform. A license proxy server is coupled to the wireless platform and the digital rights management server and communicates data therebetween. In the illustrative embodiment, the protected content is digitally rights managed email message. In more specific embodiments, a rights managed secure viewer and a secure publisher run on the wireless platform. The new content is a modified email message with the same addressee, addressor or subject of the protected content along with instructions relating to the downloading of the protected content. Code is provided on the license proxy server for retrieving a license with respect to the protected content on the execution of the instructions by a user via the wireless platform. The license is retrieved from the digital rights management server by the license proxy server. The license proxy server uses the license to decrypt the protected content using the license. The license proxy server then re-encrypts the message using an encryption algorithm that may be decrypted with a corresponding decryption algorithm stored on a rolling temporary lockbox and sends the re-encrypted message to the secure viewer. The rolling temporary lockbox is one of plural rolling temporary lockboxes. The secure viewer receives and decrypts the re-encrypted message from the lockbox and allows the user to publish protected content.

### BACKGROUND OF THE INVENTION

1. Field of the Invention

The present invention relates to computing and communications systems. More specifically, the present invention relates to systems and methods for providing for secure communications between computing platforms via a communications network.

2. Description of the Related Art

For many modern enterprises, information that is produced and consumed exists in digital form (e.g., electronic mail messages, word processing documents, spreadsheets, and databases). This digital content or data is often a valuable asset that requires protection and security. Indeed, most current and valuable enterprise information is captured in digital documents. Computers have become essential tools for processing and managing this ever-growing stockpile of information. However, enterprises are particularly challenged to protect this growing amount of valuable digital data against deliberate disclosure or accidental mishandling. For this purpose, Digital Rights Management (DRM) techniques have been employed.

As discussed in “Digital Rights Management”, DRM is any of several technologies used by publishers to control access to digital data (such as software, music, movies) and hardware. (See Wikipedia, Digital Rights Management, http://en.wikipedia.org/wiki/Digital_Rights_Management (as of Jul. 18, 2006, 02:37 GMT)). In more technical terms, DRM handles the description, layering, analysis, valuation, trading, monitoring and enforcement of usage restrictions that accompany a specific instance of a digital work.

Conventionally, DRM is implemented with a number of components distributed between a Rights Management Server and a vendor-specific client platform supported by the DRM vendor. Rights-managed documents and email messages are referred to throughout this document as ‘protected content ’. When protected content is published, the publisher specifies which individuals can access the protected content as well as what kind of access rights are granted to those individuals. Individuals to whom access rights are granted are referred to herein as ‘Principals’. Access rights determine, for example, whether the Principal can only view the information, or whether the Principal can also perform other operations such as printing, editing, or saving the information.

A ‘secure publisher’ is a software module that is primarily responsible for protecting content. ‘secure viewer’ refers to the software module that is responsible for presenting the protected content to a Principal, while enforcing access rights that potentially limit what the Principal can do with the content. The secure publisher protects the content by encrypting it, and then sealing the decryption key along with the Principals and their access rights, in a ‘Publishing License’. The secure viewer uses the publishing license to decrypt the content and enforce access rights. The secure viewing mechanism is key, because DRM is about enforcing access rights, without surrendering control of the information to the recipient of a document or email.

The secure publisher initializes the DRM lockbox that verifies that the publisher is signed by a trusted DRM authority and that the signature is valid. This ensures to the DRM lockbox that the publisher has not been tampered with. The DRM lockbox creates an empty publishing license. The DRM lockbox randomly generates a symmetric key used for Advanced Encryption Standard (AES) encryption. The DRM lockbox encrypts the symmetric key with the server's public key using the Rivest, Shamir, Adelman (RSA) public key algorithm.

The DRM lockbox returns the publishing license to the secure publisher along with an End User License (EUL). The secure publisher binds the EUL to the user's Rights-management Account Certificate (RAC), using the DRM Lockbox, resulting in an encryption handle. The secure publisher provides the encryption handle to the DRM Lockbox along with the unencrypted content. The DRM Lockbox encrypts the content using AES encryption and the symmetric key. The secure publisher then publishes the encrypted content along with the publishing license.

A secure viewer then initializes the DRM lockbox which verifies that the viewer is signed by a trusted DRM authority and that the signature is valid, thereby ensuring to the DRM lockbox that the viewer has not been tampered with. A secure viewer obtains an End User License for protected content by sending the content's publishing license to a DRM server, along with the user's RSA public key.

The DRM server authenticates the user and uses the server's RSA private key to unseal the symmetric AES key in the Publishing License. The DRM server uses the AES symmetric key to unseal the encrypted principals and rights information in the publishing license. If rights have been granted to the requesting user, then the DRM server creates an End User License by encrypting the AES symmetric key using the user's RSA public key. The secure viewer binds the EUL to the user's RAC, using the DRM Lockbox, resulting in a decryption handle. The secure viewer provides the decryption handle to the DRM Lockbox along with the encrypted content. The DRM Lockbox decrypts the content using AES encryption and the 16-byte symmetric key. The DRM Lockbox returns the decrypted content to the secure viewer. The secure viewer enforces access rights as specified in the End User License.

Although effective, the above-described technology lacks platform independence. DRM servers tend to be platform independent web services, but will generally only interoperate with their own proprietary rights management client components, which are tied to the hardware and operating system platform that the DRM vendor chooses to support.

Hence, a need remains in the art for a system or method for providing DRM for client hardware and operating system platforms beyond those supported by a DRM vendor. The need is addressed by the teachings of copending U.S. patent application Ser. No. 11/542,766 filed Oct. 4, 2006 by C. Blake et al. and entitled SYSTEM AND METHOD FOR DIGITAL RIGHTS MANAGEMENT WITH LICENSE PROXY hereinafter the ‘license proxy’ application, the teachings of which are hereby incorporated herein by reference. This application discloses and claims a digital rights management system which includes a client for publishing and/or viewing protected content; a server for providing licenses for viewing the protected content; and an inventive license proxy server coupled between the client and the server.

While the license proxy system addresses the need in the art generally, a further need remains a comparable solution for mobile wireless platforms such as the BlackBerry™ device as these devices are currently in widespread use and many in the industry expect an increase in the number of devices in use in the near future.

### SUMMARY OF THE INVENTION

The need in the art is addressed by the system and method of the present invention which provides a digital rights management system for wireless platforms. The inventive system includes client software running on the wireless platform for publishing and/or viewing protected content. Enterprise server code is executed on a first server platform for sending and receiving protected content. An inventive extension on the enterprise server code is included for detecting the presence of protected content, storing any such protected content in memory and substituting new content for the protected content for viewing on the wireless platform. A digital rights management server provides licenses for viewing the protected content on the wireless platform. A license proxy server is coupled to the wireless platform and the digital rights management server and communicates data therebetween.

In the illustrative embodiment, the protected content is digitally rights managed email message. In more specific embodiments, a rights managed secure viewer and a secure publisher run on the wireless platform. The new content is a modified email message with the same addressee, addressor or subject of the protected content along with instructions relating to the downloading of the protected content. Code is provided on the license proxy server for retrieving a license with respect to the protected content on the execution of the instructions by a user via the wireless platform. The license is retrieved from the digital rights management server by the license proxy server. The license proxy server uses the license to decrypt the protected content using the license. The license proxy server then re-encrypts the message using an encryption algorithm that may be decrypted with a corresponding decryption algorithm stored on a rolling temporary lockbox and sends the re-encrypted message to the secure viewer. The rolling temporary lockbox is one of plural rolling temporary lockboxes. The secure viewer receives and decrypts the re-encrypted message from the lockbox and displays the decrypted content to the user while enforcing access rights.

### BRIEF DESCRIPTION OF THE DRAWINGS

FIG. 1 is a simplified block diagram of a conventional infrastructure for a system for supporting the transmission and reception of email by mobile wireless devices.

FIG. 2 is a simplified block diagram of a rights managed email system as is known in the art.

FIG. 3 illustrates the use of encryption keys in accordance with conventional teachings.

FIG. 4 is a simplified block diagram showing a digital rights management scheme for wireless platforms implemented with a license proxy server in accordance with the present teachings.

FIG. 5 is a flowchart showing an operation of the secure viewer of FIG. 4 for wireless platforms in accordance with an illustrative implementation of the present teachings.

FIG. 6 is a flowchart showing the operation of the secure publisher of FIG. 4 in accordance with an illustrative embodiment of the present teachings.

FIG. 7 is diagram illustrating secure wireless protected message exchange in accordance with an illustrative embodiment of the present teachings.

FIG. 8 is a flowchart showing a protected message exchange algorithm implemented in accordance with an illustrative embodiment of the present teachings.

FIG. 9 is a diagram that illustrates a Rolling Temporary Lockbox in accordance with an illustrative embodiment of the present teachings.

FIG. 10 is a flowchart showing the operation of a Rolling Temporary Lockbox in accordance with an illustrative embodiment of the present teachings.

### DESCRIPTION OF THE INVENTION

Illustrative embodiments and exemplary applications will now be described with reference to the accompanying drawings to disclose the advantageous teachings of the present invention.

While the present invention is described herein with reference to illustrative embodiments for particular applications, it should be understood that the invention is not limited thereto. Those having ordinary skill in the art and access to the teachings provided herein will recognize additional modifications, applications, and embodiments within the scope thereof and additional fields in which the present invention would be of significant utility.

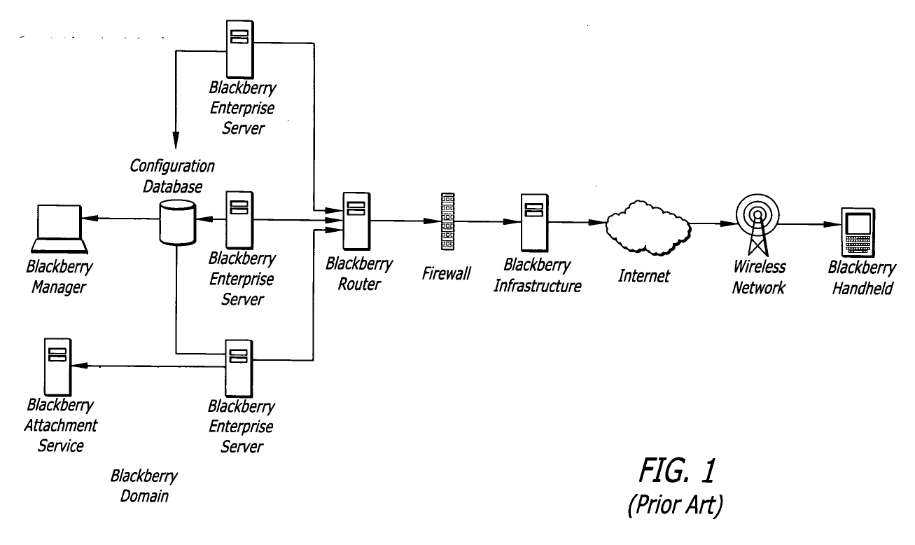

FIG. 1 is a simplified block diagram of a conventional infrastructure for a system for supporting the transmission and reception of email by mobile wireless devices. This system is typical of prior approaches which involve a ‘push’ email capability by which incoming email is sent to the handheld device as soon as it is received by the email server or as soon as is practically possible. The approach is designed to assure mobile device users of secure communications between the handheld device and the mail server. In this context, ‘secure’ means that the contents of the email messages are encrypted “on the wire” and therefore cannot be read by any third party who may try to eavesdrop on the communications.

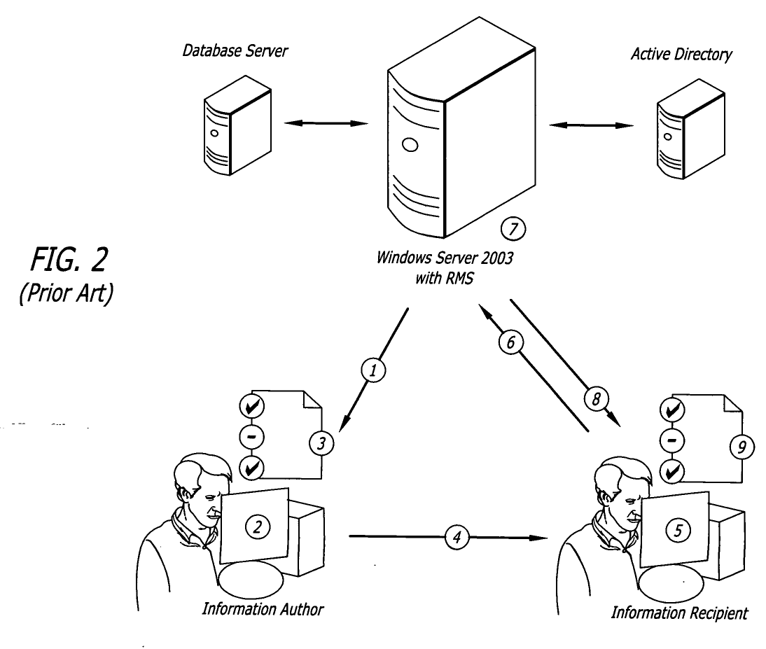

FIG. 2 is a simplified block diagram of a rights managed email system as is known in the art. These systems allow the sender of an email message to control what the recipient of the email can do with the email message. Such email systems include platform-specific secure viewers, and are implemented so that the recipient can only view the email message in a secure viewer, thereby allowing the secure viewer to enforce restrictions on what the recipient can do with the email. Depending on what rights the sender granted to the recipient, the secure viewer may prevent saving, printing, copying, or certain other operations.

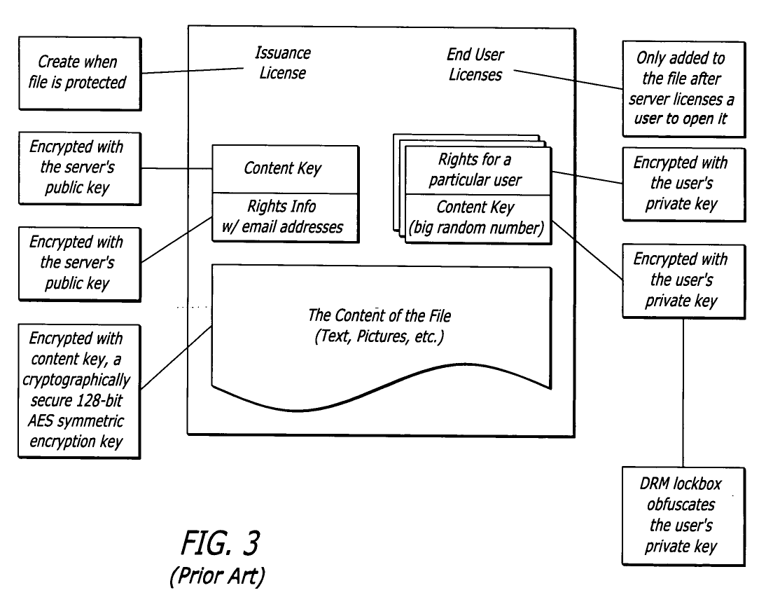

FIG. 3 illustrates the use of encryption keys in accordance with conventional teachings. In the arrangement of FIG. 3, the content is encrypted using a symmetric content key. The encrypted content is accompanied by a publishing license—also called an issuance license—that a recipient can use to request an end-user license from the Rights Management Server (RMS). Since the symmetric content key in the publishing license is encrypted using the RMS's public key, only the RMS can access the symmetric content key, using its private key to decrypt it. The RMS then re-encrypts the symmetric content key using the requesting user's public key and places the encrypted symmetric content key into an end-user license, so that only the user's private key may be used to access the symmetric content key in the end-user license.

As shown in FIG. 3, the conventional approach involves the use of a “DRM lockbox”. The term DRM lockbox refers to a mechanism wherein the user's private key is hidden from the user using standard Digital Rights Management (DRM) obfuscation algorithms, so that only the secure viewer can actually access the symmetric content key, and therefore the secure viewer is in control of the encrypted content on the recipient's computer. The DRM obfuscation algorithms try to prevent the recipient from controlling the information, and allow the secure viewer to enforce restrictions on what the recipient can do with the email message and attachments.

A specification for “Trusted Platform Modules” (TPM) in which, for the purpose of this discussion, part of the function of the DRM lockbox is performed by a microchip embedded in the recipient's PC is known in the art. (See http://en.wikipedia.org/wiki/Trusted_platform_module, as of Sep. 8, 2006.) The significance of the Trusted Platform Module's microchip is that it is believed to raise the bar for attackers wishing to defeat the DRM lockbox, such that the attacker must use specialized hardware to circumvent the TPM, in addition to hacking the DRM lockbox software.

Although the mobile wireless device infrastructure provides a basic secure transport mechanism for rights-managed emails, the support is limited to encrypting the content “on the wire”. E-mail messages are decrypted as soon as they arrive at the handheld device, and there is no secure viewer to enforce access restrictions on the content.

Another limitation in the prior art is that, with some mobile wireless systems such as Research In Motion's BlackBerry network, for rights-managed email messages, the encrypted message data is not actually transferred to the handheld device, due to the manner in which the encrypted message is stored in a special type of email attachment, combined with the fact that the infrastructure does not transfer the contents of the special email attachments to the handheld device.

Further, with some wireless mobile systems, even if the encrypted message data were transferred to the handheld device, the rights-managed email system does not include a secure viewer for the wireless handheld platform, and hence there is no mechanism either for decrypting the message content or for enforcing access restrictions to control what the recipient can do with the decrypted email message.

Finally, existing DRM lockbox implementations are somewhat static in nature. Existing DRM lockboxes are static, in the sense that a lockbox is created on the end-user's system as part of installing the DRM client software, and the same lockbox is used over and over again for controlled viewing of many documents or email messages. Furthermore, the same lockbox algorithm is applied to all users of the same release version of the DRM client software.

Also, a determined attacker may be able to defeat a DRM lockbox, as long as the attacker has been granted rights to view the content. Defeating a DRM lockbox may be less difficult than, say, defeating an encryption scheme such as AES or RSA. AES is difficult to defeat because the attacker must “guess” a secret key that is typically 128 bits long. RSA is similarly computationally difficult to defeat, assuming the attacker has the RSA public key but not the private key, but to an even greater degree of difficulty. Hence it is believed that defeating encryption schemes such as RSA and AES would take thousands of powerful computers working in concert for many years.

A DRM lockbox is much easier to defeat, because, if the attacker has rights to view a piece of content and is trying to circumvent the DRM control over the information, then the information needed to defeat the DRM is present on the attacker's system—the RSA public and private keys (in the lockbox), as well as the symmetric AES key (inside the end-user license). Typically the lynchpin to the DRM lockbox scheme is an RSA private key, which the DRM lockbox tries to hide from would-be attackers. Regardless of whether the RSA private key is hidden inside of a Trusted Platform Module microchip, defeating the DRM lockbox is merely an analytical process that can be performed on a single computer by a lone attacker.

Combining the static nature of the lockbox with the fact that a determined attacker can defeat a DRM lockbox, leads to a significant vulnerability in prior art DRM lockbox implementations. An attacker can write a program to defeat the DRM lockbox on his or her own client system, and can reuse that program to circumvent DRM protection for many documents and email messages. The attacker can also share that program with other users, who can use it to circumvent DRM protection on their documents and email messages.

Further, a DRM lockbox revocation capability is not known in the art. A DRM lockbox can be revoked for a single user or for all users of a released version of the lockbox that is known to be compromised. The revocation is limited, in that it is only effective if a security breach is discovered and steps are taken to revoke a lockbox. Also, it only prevents use of a revoked lockbox to obtain additional end-user licenses and does not prevent circumventing DRM for content for which end-users licenses have already been obtained

Hence, as mentioned above, a need remains in the art for a system or method for extending the rights-managed email capability to wireless (e.g. BlackBerry) handheld devices. The present invention addresses the need in the art by employing a license proxy and extending rights management to the wireless handheld device platforms.

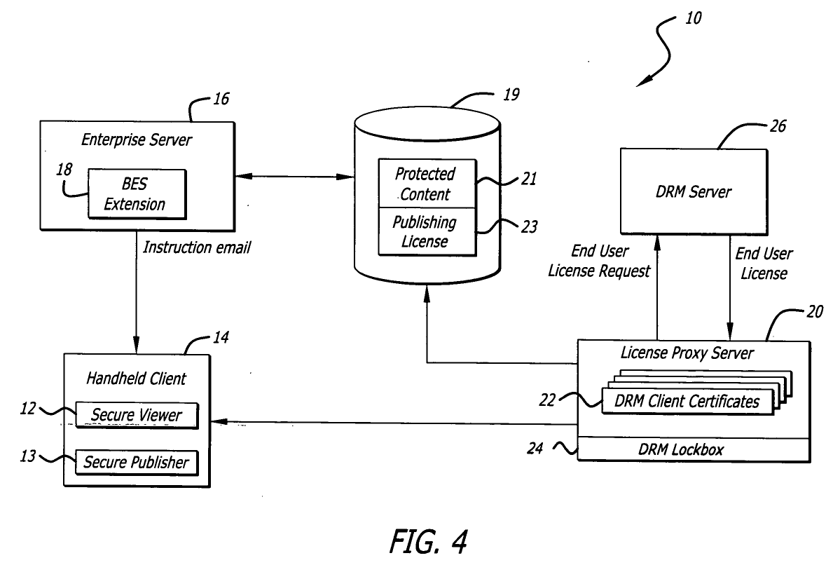

FIG. 4 is a simplified block diagram showing a digital rights management scheme for wireless platforms implemented with a license proxy server in accordance with the present teachings. In the illustrative embodiment, the invention is adapted for use with a Blackberry™ wireless handheld device. Nonetheless, those skilled in the art will appreciate that the invention is not limited thereto. That is, the present teachings may be applied to other handheld devices without departing from the scope of the present teachings.

As shown in FIG. 4, the system 10 implements a rights-management secure viewer 12 on a wireless handheld device 14 which displays rights-managed email messages to the recipient and enforces access restrictions. Also included is a secure publisher 13 that enables a user to create and transmit rights-managed email messages.

The system 10 includes a wireless enterprise server 16 with a Blackberry Enterprise Server (BES) extension 18, a cache 19 for storing protected content and a publishing license, a license proxy server 20 with DRM client certificates 22 and a DRM lockbox 24, and a DRM server 26. The license proxy server 20 and the DRM server 26 may be implemented in accordance with the teachings of the above-referenced patent filed by Blake et al. and entitled SYSTEM AND METHOD FOR DIGITAL RIGHTS MANAGEMENT WITH LICENSE PROXY, the teachings of which are incorporated herein by reference.

The BES extension 18 is a component of the inventive system that modifies the behavior of the wireless mail system. Such components may be referred to by various names such as filters, sinks, or extensions. In FIG. 4, the wireless email system includes a component called the BlackBerry Enterprise Server (BES), and the inventive system includes an extension module called a BES Extension, which affects how the BES processes mail messages for transmission to handheld devices. The cache 19 could be any type of data repository and may be physically located on any data storage system that is accessible both by the BES and the license proxy server.

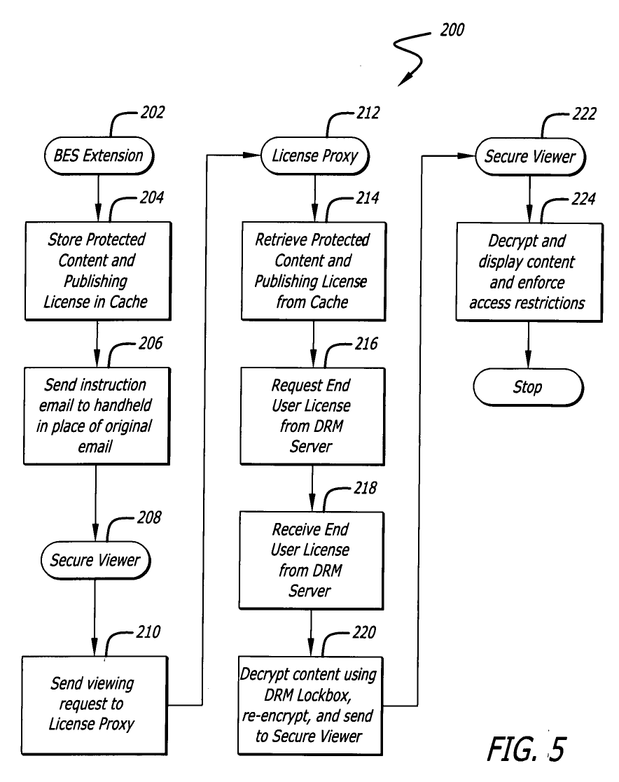

FIG. 5 is a flowchart showing the operation of the secure viewer of FIG. 4 for wireless platforms in accordance with an illustrative implementation of the present teachings. At step 204, the BES extension 18 stores protected content 21 along with the content's publishing license 23 in the cache 19 upon receiving an email message before it is transmitted to a handheld device. At step 206, the BES extension 18 replaces the email message body with an instructional email that tells the recipient how to view the protected content on the handheld device. As per standard message handling on the handheld device, the protected email message is listed in the mail application's “inbox”.

When the user reads the email message on the handheld, the message body informs the user that the email message is protected, and instructs the user how to view the email message. A “Quick View” menu item is displayed among the list of available operations, which will automatically process and display the most recent message in the current message's email thread.

Alternatively, the user can selected a particular message in the current message's thread, and a “View With GigaTrust” menu item is displayed. After the user has selected either “Quick View” or “View With GigaTrust”, the secure viewer at step 210 sends a request to the license proxy to process the appropriate email message.

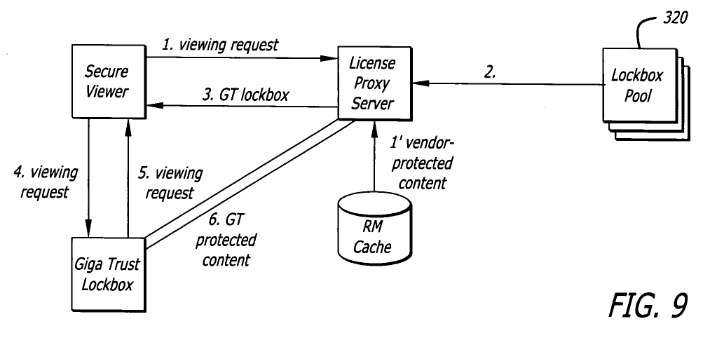

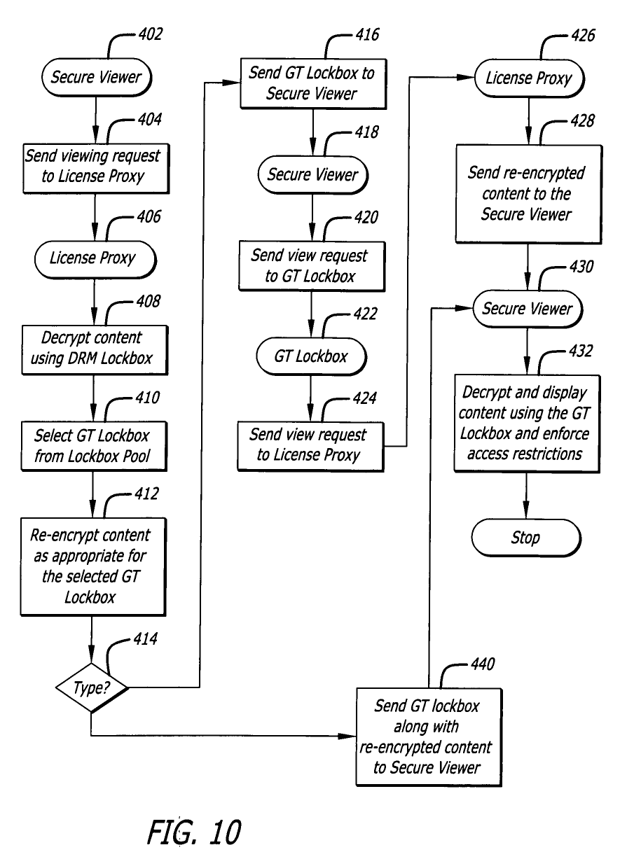

Since the protected message contents were never actually transmitted to the handheld device, as per normal BlackBerry operating practices, but instead only placeholders were transmitted, the secure viewer 12 identifies the appropriate email message by unique message identifier as assigned by the BlackBerry system, along with an associated attachment name if any. At step 214, upon receiving this request, the license proxy 20, will retrieve the message contents from the cache 19, the message contents having been previously written to the cache 19 by the BES extension 18. At step 216, on behalf of the requesting user, the license proxy 20 will request (step 216) and receive (step 218) an end-user license from the DRM Server, according to the requirements of the DRM vendor, using the vendor's DRM Lockbox 24. At step 220, the license proxy 20 will use the end-user license and DRM lockbox to decrypt the message contents. The license proxy 20 then re-encrypts the content according to a rolling temporary lockbox mechanism described below in the discussion of FIGS. 9 and 10. The license proxy 20 sends the re-encrypted content back to the secure viewer. At step 224, the secure viewer 20, decrypts and displays the content and enforces access restrictions.

Note that there are some cases where the protected content is present on the handheld device 14 and is not stored in the cache 19. For example, after a user creates a protected email on the handheld device 14 using the secure publisher 13 the user will then be able to view the protected content from his or her “sent items” list. In this case, the handheld device 14 will send the protected content 21 to the license proxy 20 as part of the viewing request, instead of sending a unique message identifier. Upon receipt of the protected content as part of the viewing request, the license proxy 20 will use the protected content contained in the request, instead of retrieving the protected content from the cache 19.

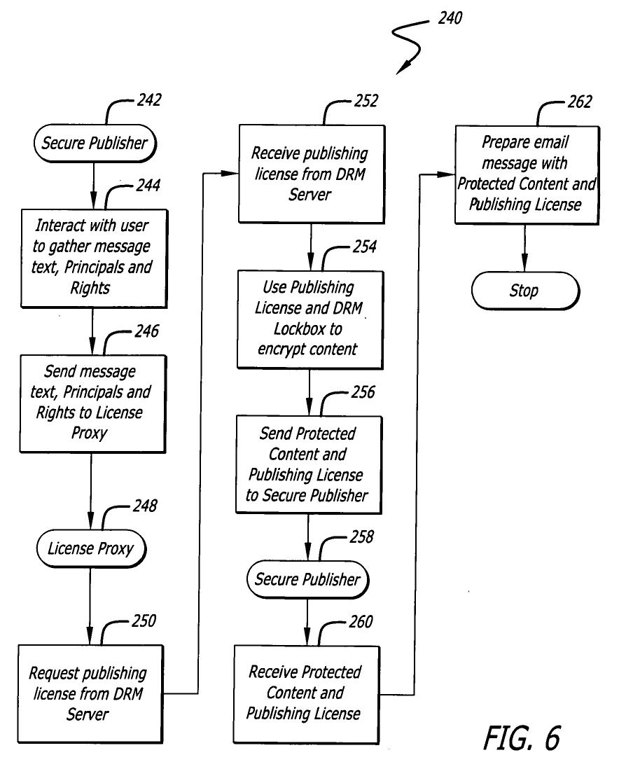

FIG. 6 is a flowchart showing the operation of the secure publisher of FIG. 4 in accordance with an illustrative embodiment of the present teachings. As illustrated in FIG. 6, at step 244, the secure publisher 13 interacts with the user to obtain the message text, the recipient email addresses as the Principals who will be granted rights to access the content, and the rights to be granted to those Principals. The user actually composes the email message, per the typical procedure for sending unprotected email messages, and then selects a menu item e.g. “Protect with GigaTrust”, at which point the secure publisher automatically gathers the Principal email addresses from the email message header, and prompts the user for the rights to be granted.

At step 246, the secure publisher sends the message text, Principals, and rights to the license proxy server 20 (FIG. 4). At steps 250 and 252, the license proxy server 20, requests and receives a publishing license from the DRM Server, specifying in the request the list of Principals and rights granted. At step 254, the license proxy server uses the publishing license along with the DRM Lockbox (24) to encrypt the message text. At step 256, the license proxy server then sends the protected content and publishing license to the secure publisher.

At step 260, the secure publisher receives the protected content and Publishing License. At step 262, the secure publisher prepares an email message containing the protected content and Publishing License, which the user can review and send at any time.

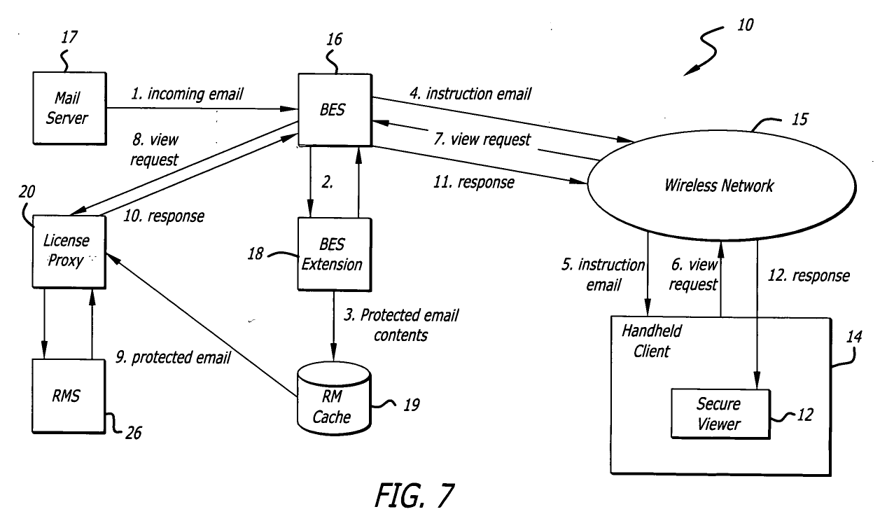

FIG. 7 is diagram illustrating a secure and unique wireless message exchange protocol for protected content, in accordance with an illustrative embodiment of the present teachings. FIG. 7 illustrates a feature of the invention in which protected content may be retained in a repository, also known as a cache, while at the same time a “place holder” email message is sent to a handheld device, so that the recipient may issue a viewing request from a handheld device, and only then is the content actually delivered to the handheld device. There are three reasons why this feature is important. First, wireless transmission bandwidth is a valuable resource and, for the sake of cost and efficiency, there is little value in sending the protected content to the handheld until it has been processed by the license proxy server so that it can be decrypted by the secure viewer.

Second, the recipient may choose not to view the protected content on the handheld device, for whatever reason, opting instead to read the protected content on another device such as a desktop computer.

Third, some wireless email providers such as BlackBerry only send certain types of content to handheld devices and therefore may not send the protected content as part of the normal “push” email delivery mechanism.

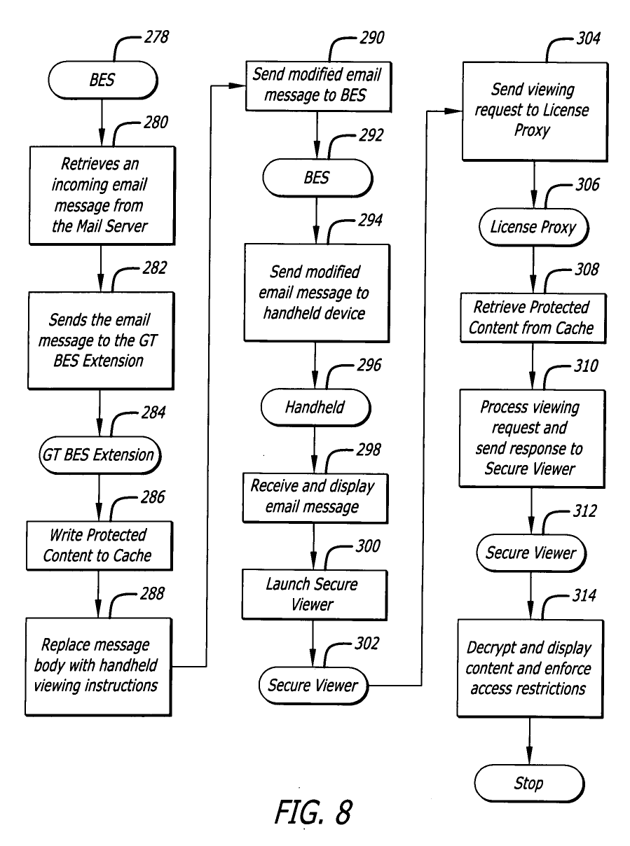

FIG. 8 is a flowchart showing the secure and unique wireless message exchange protocol for protected content depicted in FIG. 7 and implemented in accordance with an illustrative embodiment of the present teachings. In step 280, the BES 16 (FIG. 6), retrieves a newly received email message from the mail server 17 and in step 282, sends the email message to the BES extension 18.

The BES extension detects whether the email message contains protected content and, if so, at step 286, writes the protected content, including its associated publishing license, to a cache, which can be any type of data repository. At step 288, the BES extension, replaces the email message body with instructions for viewing the protected content on a handheld device. Note that the BES extension acts upon a copy of the email message that will be delivered only to a handheld device. The recipient may choose to view the same email message using a desktop computer system, in which case the recipient would see the email message originally received by the mail server, and not the one that was modified by the BES extension for viewing on a handheld device.

After caching the protected content and replacing the message body with handheld viewing instructions, at step 290, the BES extension sends the modified email message to the BES. In step 294, the BES sends the modified email message to the handheld device through the wireless network. At step 298, the handheld device receives the email message and displays it in the recipient's “inbox” according to the normal operation of the mail application on the handheld device.

As discussed earlier in this document, the user can, by various means, launch the secure viewer to view the protected content contained in the email message, as shown in step 300. At step 304, the secure viewer sends a viewing request to the license proxy, identifying the protected content by a unique message identifier and attachment name. At step 308, the license proxy retrieves the protected content from the cache, and at step 310, processes the viewing request as described above and sends a response to the secure viewer 12 (FIG. 4). At step 314, the secure viewer decrypts and displays the protected content and enforces access restrictions.

Returning briefly to FIG. 4, note that there may be cases where the protected content is present on the handheld device and not stored in the cache. For example, after a user creates a protected email on the handheld device using the secure publisher 13, the user will then be able to view the protected content from his or her “sent items” list. In this case, the handheld device 14 will send the protected content 21 to the license proxy server 20 as part of the viewing request, instead of just sending a unique message identifier. Upon receipt of the protected content as part of the viewing request, the license proxy 20 will use the protected content 21 contained in the request, instead of retrieving the protected content from the cache 19.

FIG. 9 is a diagram that illustrates a Rolling Temporary Lockbox in accordance with an illustrative embodiment of the present teachings. As discussed previously with regard to FIG. 3, digital rights management systems typically include a “lockbox”, which generically refers to any obfuscation method employed by the DRM system to prevent users who have some rights to access protected content, from acquiring more rights than they have been granted by the author, or from bypassing the DRM access restrictions altogether. In this way, DRM differs from traditional cryptography. Traditional cryptography endeavors to prevent an eavesdropper, who does not possess a decryption key, from decrypting protected communication by cracking the code or breaking the encryption algorithm. DRM also endeavors to thwart such eavesdropping threats, but, in addition, DRM must thwart legitimate users who do possess the decryption key or the decrypted content, and must prevent these legitimate users from somehow gaining access to the decrypted content outside of the DRM system, where there are no controls on what happens to the content. Typically, a DRM system thwarts legitimate users who may try to bypass DRM controls, by hiding the decryption key via some mechanism called a “lockbox”.

As shown in FIG. 9, the invention includes a unique lockbox mechanism, whereby the secure viewer, after sending a viewing request to the license proxy server, receives a lockbox from the license proxy server, either separately or in combination with the protected content. The license proxy server chooses the lockbox from a lockbox pool, 320 via a secret algorithm and encrypts the protected content in such a way that only the selected lockbox will be able to decrypt the content.

Note that the lockbox may be one of several factors needed by the secure viewer in order to decrypt the content and is not necessarily the only means of protecting the content. If an attacker goes to the trouble of reverse engineering the secure viewer and lockbox in order to bypass the DRM controls on a particular piece of content, this rolling temporary lockbox mechanism limits the value to the attacker of that accomplishment, because the attacker may never receive any other content protected using the same lockbox. This differs from typical DRM implementations where, once an attacker has broken the lockbox, the algorithm for breaking the lockbox can be implemented in a software program that can then be used to access any protected content to which the user has been granted access.

FIG. 10 is a flowchart showing the operation of a Rolling Temporary Lockbox in accordance with an illustrative embodiment of the present teachings. As illustrated in FIG. 10, at step 404, the secure viewer sends a viewing request to the license proxy server. The viewing request may include the protected content, or it may include a unique identifier that the license proxy can use to retrieve the protected content from back-end storage. The license proxy obtains an end-user license from the DRM Server and uses the DRM Lockbox to decrypt the protected content, as shown at step 408. At step 410, the license proxy chooses an appropriate, e.g., GigaTrust Lockbox (GT Lockbox) from a pool of available lockboxes. Each lockbox embodies a different decryption scheme as well as various security mechanisms designed to thwart attackers who may be trying to view content they do not have rights to view, as specified by the user that protected the content, and also to thwart attackers who may have some assigned rights, but are trying to “hack” the system in order to obtain additional rights. The pool of available lockboxes is theoretically infinite, as new lockboxes can continually be created.

The license proxy chooses a lockbox in a way that is intended to maximize the variety of lockboxes that a would-be attacker is likely to be confronted with, so that if the attacker succeeds in overcoming the protection of a single lockbox, the amount of data that would be compromised is minimal. A lockbox embodies a particular decryption scheme, and the license proxy implements the corresponding encryption scheme. Therefore the license proxy must implement a number of encryption schemes, with each one corresponding to a lockbox in the lockbox pool. The license proxy keeps track of which encryption scheme corresponds to each GT Lockbox in the pool.

In step 412, the license proxy re-encrypts the content using the encryption scheme that corresponds to the selected GT lockbox. Then, depending on the type of lockbox, the license proxy will either send just the GT Lockbox to the secure viewer, as shown in step 416, or it will send the GT Lockbox along with the re-encrypted content to the secure viewer, as shown in step 440. If only the GT Lockbox is sent, then secure viewer requests the re-encrypted content from the GT Lockbox, which in turn requests the re-encrypted content from the license proxy, as shown in steps 420, 424, and 428. Eventually, regardless of which execution path is taken, the secure viewer will possess both a GT lockbox and the re-encrypted content, and therefore at step 432 the secure viewer will use the GT Lockbox to decrypt the content and will then display the decrypted content to the user and enforce access restrictions.

Hence, the present invention addresses the need in the art by using a license proxy server to extend rights management to the wireless handheld device platforms:
1. Through the implementation of a rights-management secure viewer that runs on a wireless handheld device, displays rights-managed email messages to the recipient and enforces access restrictions. (FIG. 4)
2. Through the implementation of a rights-management secure publisher that runs on the handheld device, which allows a handheld user to encrypt an email message and assign access restrictions, before sending the email. (FIG. 4)
3. Through the implementation of a unique message exchange mechanism between the wireless Enterprise Server and the license proxy server, that overcomes the prior art limitation in which rights-managed email content is not actually transferred to the handheld devices by the BlackBerry infrastructure. (FIG. 7) The inventive unique message exchange mechanism also provides significantly improved network bandwidth utilization, in typical usage scenarios where recipients delete some email messages from the handheld device without reading them, preferring instead to open some email messages for the first time on a desktop computer.
4. Through the implementation of a “rolling temporary lockbox” mechanism, in which the license proxy hosts a number of different DRM lockbox algorithms, and, as part of each viewing transaction, the license proxy determines which lockbox algorithm the end user must use, in order to view the requested content, and also downloads the selected lockbox to the end user as part of the viewing transaction. Theoretically, every viewing transaction could deploy a new lockbox implementation to the end user. (FIG. 8)
A determined attacker may be able to defeat a conventional lockbox for a particular document or email message, however, by deploying different lockboxes for different content and different users in accordance with the present teachings, the rolling temporary lockbox mechanism prevents the attacker from developing a program that can be used by the attacker or by other users, to automatically circumvent DRM for any document or email message.

Thus, the present invention has been described herein with reference to a particular embodiment for a particular application. Those having ordinary skill in the art and access to the present teachings will recognize additional modifications, applications and embodiments within the scope thereof. For example, those skilled in the art will appreciate that the processes depicted in the flow diagrams shown and described herein may be implemented in software, using C++, Java, C#, or other suitable language, stored on a machine readable physical storage medium and adapted for execution by a processor or general purpose digital computer without departing from the scope of the present teachings.

It is therefore intended by the appended claims to cover any and all such applications, modifications and embodiments within the scope of the present invention.

Accordingly,

What is claimed is:

1. A digital rights management system for wireless platforms comprising:
client means for publishing and/or viewing protected content on a wireless platform;
enterprise server means for sending and receiving protected content;
enterprise server extension means for detecting the presence of protected content at said enterprise server, for storing any such protected content in memory and for substituting new content for said protected content for viewing on said wireless platform;
digital rights management server means for providing licenses for viewing said protected content on said wireless platform; and
a license proxy server coupled to said client means and said digital rights management server means.

2. The invention of claim 1 wherein said protected content is digitally rights managed content.

3. The invention of claim 1 further including a rights managed secure viewer running on said wireless platform.

4. The invention of claim 3 further including a rights managed secure publisher running on said wireless platform.

5. The invention of claim 4 wherein said protected content is an email message.

6. The invention of claim 5 wherein said new content is a modified email message.

7. The invention of claim 6 wherein said modified email message has the same addressee, addressor or subject of said protected content.

8. The invention of claim 7 wherein said modified message includes instructions relating to the downloading of the protected content.

9. The invention of claim 8 further including means for retrieving a license with respect to said protected content on the execution of said instructions by a user via said wireless platform.

10. The invention of claim 9 wherein said means for retrieving a license is computer code disposed on a machine readable medium for execution by said license proxy server.

11. The invention of claim 10 wherein said license is retrieved from said digital rights management server means.

12. The invention of claim 11 further including code on said license proxy server for decrypting said protected content using said license.

13. The invention of claim 12 further including code on said license proxy server for re-encrypting said message using an encryption algorithm that may be decrypted with a corresponding decryption algorithm stored on a rolling temporary lockbox and for sending the re-encrypted message to said secure viewer.

14. The invention of claim 13 wherein said rolling temporary lockbox is one of plural rolling temporary lockboxes.

15. The invention of claim 13 further including computer code disposed on a machine readable medium for execution by said secure viewer for receiving and decrypting said re-encrypted message.

16. The invention of claim 1 wherein said wireless platform is a Blackberry™ wireless handheld device.

17. The invention of claim 1 including means for viewing said protected email message on a desktop platform.

18. A digital rights management system for wireless platforms comprising:
client software stored on a machine readable medium running on a wireless platform for publishing and/or viewing protected content;
enterprise server code stored on a machine readable medium running on a first server platform for sending and receiving protected content and for detecting the presence of protected content, for storing any such protected content in memory and substituting new content for said protected content for viewing on said wireless platform;
a digital rights management server with code stored on a machine readable medium for providing licenses for viewing said protected content on said wireless platform; and
a license proxy server coupled to said wireless platform and said digital rights management server.

19. The invention of claim 18 wherein said protected content is digitally rights managed content.

20. The invention of claim 18 further including a rights managed secure viewer running on said wireless platform.

21. The invention of claim further 20 including a rights managed secure publisher running on said wireless platform.

22. The invention of claim 21 wherein said protected content is an email message.

23. The invention of claim 22 wherein said new content is a modified email message.

24. The invention of claim 23 wherein said modified email message has the same addressee, addressor or subject of said protected content.

25. The invention of claim 24 wherein said modified message includes instructions relating to the downloading of the protected content.

26. The invention of claim 25 further including code for retrieving a license with respect to said protected content on the execution of said instructions by a user via said wireless platform.

27. The invention of claim 26 wherein said code for retrieving a license is computer code disposed on a machine readable medium for execution by said license proxy server.

28. The invention of claim 27 wherein said license is retrieved from said digital rights management server means.

29. The invention of claim 28 further including code on said license proxy server for decrypting said protected content using said license.

30. The invention of claim 29 further including code on said license proxy server for re-encrypting said message using an encryption algorithm that may be decrypted with a corresponding decryption algorithm stored on a rolling temporary lockbox and for sending the re-encrypted message to said secure viewer.

31. The invention of claim 30 wherein said rolling temporary lockbox is one of plural rolling temporary lockboxes.

32. The invention of claim 30 further including computer code disposed on a machine readable medium for execution by said secure viewer for receiving and decrypting said re-encrypted message.

33. The invention of claim 18 wherein said wireless platform is a Blackberry™ wireless handheld device.

34. The invention of claim 18 including means for viewing said protected email message on a desktop platform.

35. A digital rights management method for wireless platforms including the steps of:
publishing and/or viewing protected content on a wireless client platform;
sending and receiving protected content via an enterprise server;
detecting the presence of protected content at said enterprise server, storing any such protected content in memory and substituting new content for said protected content for viewing on said wireless platform via an extension on code running on said enterprise server;
providing licenses for viewing said protected content on said wireless platform using a digital rights management server; and
sending data between said client and said digital rights management server via a license proxy server.

36. The invention of claim 35 wherein said protected content is digitally rights managed content.

37. The invention of claim 35 further including a rights managed secure viewer running on said wireless platform.

38. The invention of claim 37 further including a rights managed secure publisher running on said wireless platform.

39. The invention of claim 38 wherein said protected content is an email message.

40. The invention of claim 39 wherein said new content is a modified email message.

41. The invention of claim 40 wherein said modified email message has the same addressee, addressor or subject of said protected content.

42. The invention of claim 41 wherein said modified message includes instructions relating to the downloading of the protected content.

43. The invention of claim 42 further including the step of retrieving a license with respect to said protected content on the execution of said instructions by a user via said wireless platform.

44. The invention of claim 43 wherein said step of retrieving a license is implemented by computer code disposed on a machine readable medium for execution by said license proxy server.

45. The invention of claim 44 wherein said license is retrieved from said digital rights management server.

46. The invention of claim 45 further including the step of decrypting said protected content using said license.

47. The invention of claim 46 further the step of re-encrypting said message using a rolling temporary lockbox and sending a re-encrypted message to said secure viewer.

48. The invention of claim 47 wherein said rolling temporary lockbox is one of plural rolling temporary lockboxes.

49. The invention of claim 47 further including the step of receiving and decrypting said re-encrypted message.

50. The invention of claim 35 wherein said wireless platform is a Blackberry™ wireless handheld device.
